(19) United States
(12) Patent Application Publication
(10) Pub. No.: US 2018/0182877 A1
(43) Pub. Date: Jun. 28, 2018

(54) SEMICONDUCTOR STRUCTURES AND METHOD FOR FABRICATING THE SAME

(71) Applicant: Industrial Technology Research Institute, Hsinchu (TW)

(72) Inventors: Li-Heng Lee, Yunlin County (TW); Yu-Sheng Chen, Taoyuan City (TW)

(21) Appl. No.: 15/608,949

(22) Filed: May 30, 2017

(30) Foreign Application Priority Data
Dec. 28, 2016 (CN) 201611237175.X

(51) Int. Cl. H01L 29/778; H01L 21/8238; H01L 29/423; H01L 21/02

(52) U.S. Cl. CPC H01L 29/778; H01L 21/8238; H01L 21/02389; H01L 21/02123; H01L 21/02293; H01L 29/4236

(57) ABSTRACT

A semiconductor structure is provided. The semiconductor structure includes a silicon substrate having a groove, an epitaxial layer disposed on the sidewalls of the groove, and a gate disposed above the epitaxial layer and electrically connected to the epitaxial layer. The sidewalls of the groove have a lattice direction of (111). The groove extends in a first direction. The semiconductor structure and its fabrication method make a complementary metal oxide semiconductor (CMOS) circuit and a high electron mobility transistor (HEMT) with high electron mobility, high breakdown voltage and heat resistance properties being capable of being integrated on the same silicon (100) substrate at the same time to enhance the ability of the system on chip to handle power and RF power signals.

### CROSS REFERENCE TO RELATED APPLICATIONS

This application claims priority of China Patent No. 201611237175.X, filed on Dec. 28, 2016, the entirety of which is incorporated by reference herein.

### TECHNICAL FIELD

The disclosure relates to a semiconductor structure with a high electron mobility transistor (HEMT) disposed on a silicon (100) substrate and a method for fabricating the same.

### BACKGROUND

GaN and SiC are semiconductors with excellent physical properties, such as large bandgap, high electric breakdown field and relatively high electron mobility. Devices fabricated on these two semiconductors are especially suitable for power electronic applications. Today, high-quality SiC substrates have been well developed, which have a reasonable cost, and related processing technology, like implant and thermal processes have also been perfected, gradually reached the qualified production level. SiC has been used for fabricating Schottky barrier diodes, BJTs, MOSFETs and more. However, the quality of GaN substrates still has not reached a level for high-performance devices, despite longtime research. However, GaN and other related Group III-nitride materials can be perfectly grown on substrates like Sapphire, AlN, and SiC. Studies show that the Group III-nitride semiconductors of a hetero-structure of AlGaN/GaN are an excellent material system for fabricating high electron mobility transistors (HEMT). The structure supplies an excellent and unique combination of high carrier concentration and high carrier mobility. A two-dimensional electronic layer with an ultra-high concentration of electrons, ˜10¹³/cm², is formed at the heterojunction of the Group III-nitride material system, without any doping. The mobility of the carriers in the quantum well formed from the heterojunction between GaN and AlGaN can be as high as 2,000 cm²/Vs. Their combined properties offer enormous potential for the application of Group III-V materials in both power and RF electronics.

In early days, most of these Group III-nitride devices were fabricated on SiC substrates. Despite having the best performance, especially in power management applications, Group III-nitride devices fabricated on SiC have the disadvantage of a very high cost. To reduce the cost, the device fabricated on a Si substrate was developed. Si crystal in (111) orientation shows a hexagonal lattice, which is the same as the lattice structure of the Group III-nitride in the c-axis. There is an acceptable lattice mismatch of ˜16% therebetween. Therefore, the junction between the two hetero-semiconductors can achieve a fairly good match. The Group III-nitride device fabricated on a Si (111) substrate shows both good power and RF performance. Compared to the SiC-substrate, the Si (111) substrate also provides a more affordable and lower cost alternative. However, silicon (111) substrates are not the mainstream in the current industry. In further consideration of reducing the cost of material acquisition and management, there is still a strong incentive to continue to seek silicon (100) as the substrate.

The mainstream Si-based CMOS industry has been built on the Si (100) substrate. If a Group III-nitride can also be fabricated on a Si (100) substrate, the Group III-nitride devices will not only benefit from the low cost of mainstream supply, but also open the possibility of integrating the Group III-nitride devices into the CMOS SOCs.

### SUMMARY

One embodiment of the disclosure provides a semiconductor structure comprising a silicon substrate having a groove with sidewalls, an epitaxial layer disposed on the sidewalls of the groove, and a gate disposed above the epitaxial layer and electrically connected to the epitaxial layer. The sidewalls of the groove have a lattice direction of (111). The groove extends in a first direction.

One embodiment of the disclosure provides a method for fabricating a semiconductor structure, comprising the following steps. A silicon substrate is provided. The silicon substrate is etched to form a groove with sidewalls in the silicon substrate. An epitaxial layer is formed on the sidewalls of the groove. A gate is formed above the epitaxial layer to electrically connect to the epitaxial layer. The sidewalls of the groove have a lattice direction of (111). The groove extends in a first direction.

A detailed description is given in the following embodiments with reference to the accompanying drawings.

### BRIEF DESCRIPTION OF THE DRAWINGS

The present disclosure can be more fully understood by reading the subsequent detailed description and examples with references made to the accompanying drawings, wherein:

FIG. 1A is a cross-sectional view of a semiconductor structure in accordance with one embodiment of the disclosure;

FIG. 1B is a top view of the semiconductor structure shown in FIG. 1A;

FIG. 2A is a cross-sectional view of a semiconductor structure in accordance with one embodiment of the disclosure;

FIG. 2B is a top view of the semiconductor structure shown in FIG. 2A;

FIG. 3A is a cross-sectional view of a semiconductor structure in accordance with one embodiment of the disclosure;

FIG. 3B is a top view of the semiconductor structure shown in FIG. 3A;

FIGS. 4A-4M is a cross-sectional view of a method for fabricating a semiconductor structure in accordance with one embodiment of the disclosure;

FIGS. 5A-5I is a cross-sectional view of a method for fabricating a semiconductor structure in accordance with one embodiment of the disclosure;

FIG. 6 is a cross-sectional view of a semiconductor structure in accordance with one embodiment of the disclosure; and

FIG. 7 is a cross-sectional view of a semiconductor structure in accordance with one embodiment of the disclosure.

### DETAILED DESCRIPTION

In the following detailed description, for the purposes of explanation, numerous specific details are set forth in order to provide a thorough understanding of the disclosed embodiments. It will be apparent, however, that one or more embodiments may be practiced without these specific details. In other instances, well-known structures and devices are shown schematically in order to simplify the drawing.

In order to meet the current situation of using silicon (100) substrate as the main substrate in the Si-based CMOS industry, to find lower-cost materials, and to effectively utilize the excellent ability of processing power and radio frequency (RF) signals of the Group III-nitride devices, the present disclosure provides a semiconductor structure with a high electron mobility transistor (HEMT) disposed on a silicon (100) substrate and a method for fabricating the same.

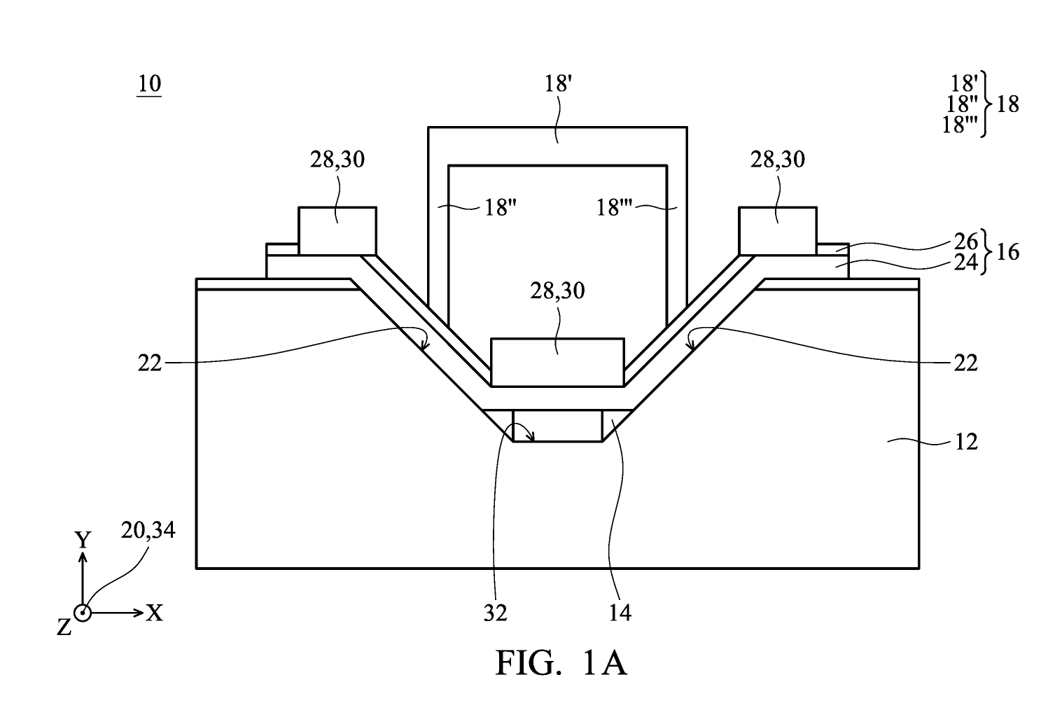

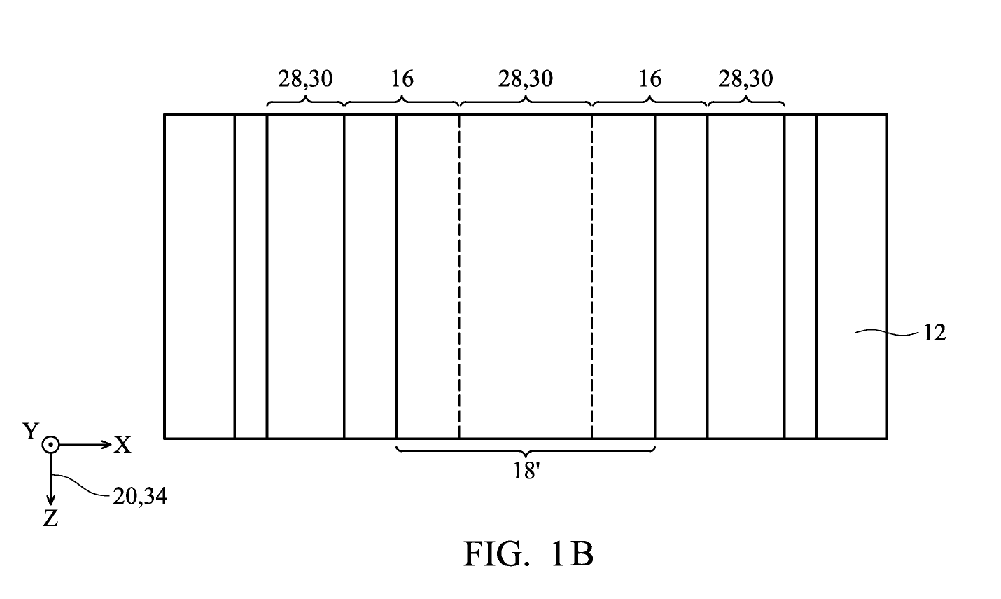

Referring to FIGS. 1A and 1B, in accordance with one embodiment of the disclosure, a semiconductor structure 10 is disclosed. FIG. 1A is a cross-sectional view of the semiconductor structure 10. FIG. 1B is a top view of the semiconductor structure 10 shown in FIG. 1A.

In this embodiment, the semiconductor structure 10 comprises a silicon substrate 12, a groove 14 having a bottom 32 and sidewalls 22, an epitaxial layer 16, and a gate 18. The groove 14 is disposed in the silicon substrate 12 and extends in a first direction 20, such as the z direction. The epitaxial layer 16 is disposed on the sidewalls 22 of the groove 14 and is extended above the bottom 32 of the groove 14 and the silicon substrate 12. The gate 18 is disposed above the epitaxial layer 16 and electrically connected to the epitaxial layer 16. In one embodiment, the sidewalls 22 of the groove 14 have a lattice direction of (111). The epitaxial layer 16 comes into contact with a dielectric material layer 42 within the groove 14. The dielectric material layer 42 is located above the silicon substrate 12.

In this embodiment, the base of the silicon substrate 12 has a lattice direction of (100).

In this embodiment, the sidewalls 22 of the groove 14 are inclined planes. The two inclined planes form an angle therebetween.

In this embodiment, the epitaxial layer 16 comprises a GaN layer 24 and an AlGaN layer 26 disposed thereon.

In other embodiments, the epitaxial layer 16 may also comprise any monolayer or multilayers and suitable Group III-nitride layers.

In this embodiment, the semiconductor structure 10 further comprises a buffer layer (not shown) disposed between the silicon substrate 12 and the epitaxial layer 16.

In this embodiment, as shown in FIG. 1A, the gate 18 comprises a first portion 18′, a second portion 18″ and a third portion 18′″. The first portion 18′ is substantially parallel to the silicon substrate 12. The second portion 18″ is connected to one end of the first portion 18′ and the epitaxial layer 16. The third portion 18′″ is connected to the other end of the first portion 18′ and the epitaxial layer 16.

In this embodiment, the semiconductor structure 10 further comprises a source/drain (28/30) respectively disposed above the silicon substrate 12 and the bottom 32 of the groove 14. The gate 18 and the source/drain (28/30) extend in a second direction 34, for example the z direction. The second direction 34 is parallel to the first direction 20.

In this embodiment, the source/drain (28/30) comprises a composite material of titanium, aluminum, nickel and silver.

In other embodiments, the source/drain (28/30) may also comprise any suitable metal or alloy material thereof.

In other embodiments, the source/drain (28/30) may further be disposed above the sidewalls 22 of the groove 14, as shown in FIG. 1A.

In other embodiments, a channel (not shown) is formed along the sidewalls 22 of the groove 14. The extension direction of the channel is perpendicular to the first direction 20.

In this embodiment, the epitaxial layer 16, the gate 18 and the source/drain (28/30) constitute a high electron mobility transistor (HEMT).

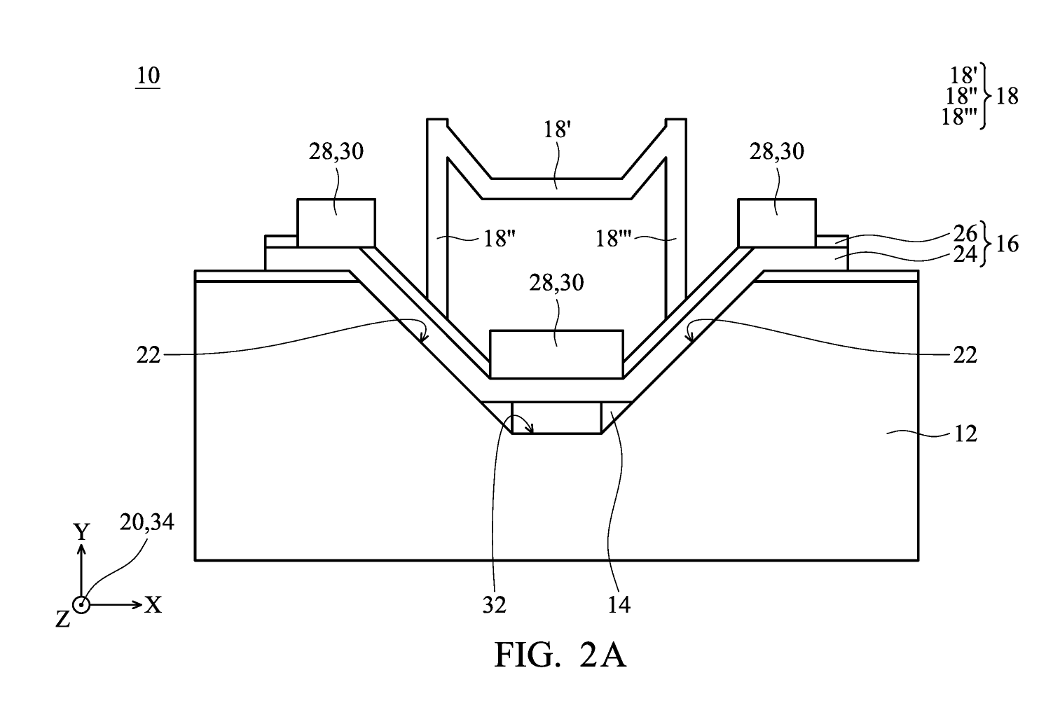

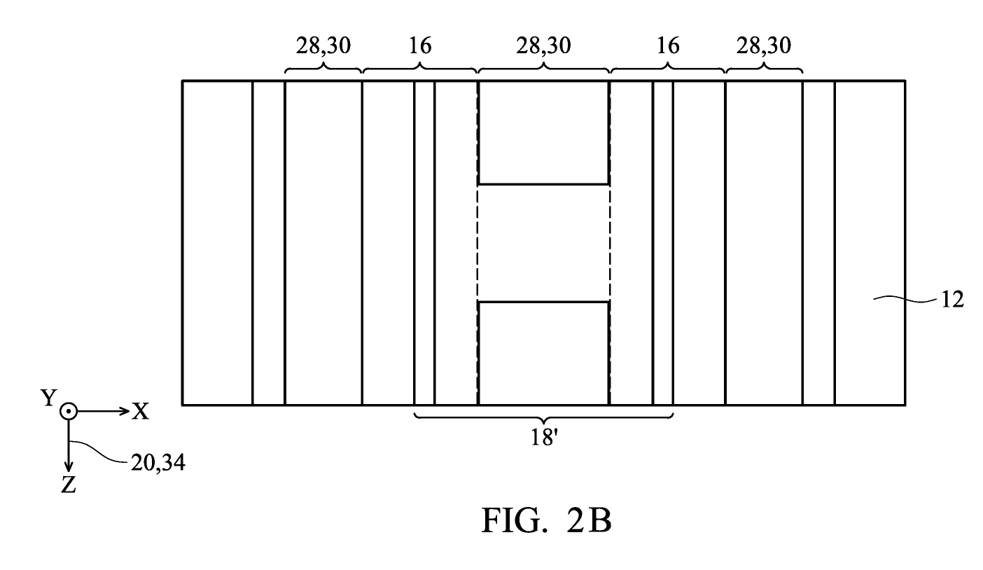

Referring to FIGS. 2A and 2B, in accordance with one embodiment of the disclosure, a semiconductor structure 10 is disclosed. FIG. 2A is a cross-sectional view of the semiconductor structure 10. FIG. 2B is a top view of the semiconductor structure 10 shown in FIG. 2A.

In this embodiment, the semiconductor structure 10 comprises a silicon substrate 12, a groove 14 having a bottom 32 and sidewalls 22, an epitaxial layer 16, and a gate 18. The groove 14 is disposed in the silicon substrate 12 and is extended in a first direction 20, for example the z direction. The epitaxial layer 16 is disposed on the sidewalls 22 of the groove 14 and is extended above the bottom 32 of the groove 14 and the silicon substrate 12. The gate 18 is disposed above the epitaxial layer 16 and electrically connected to the epitaxial layer 16. In one embodiment, the sidewalls 22 of the groove 14 have a lattice direction of (111). The epitaxial layer 16 comes into contact with a dielectric material layer 42 within the groove 14. The dielectric material layer 42 is located above the silicon substrate 12.

In this embodiment, the base of the silicon substrate 12 has a lattice direction of (100).

In this embodiment, the sidewalls 22 of the groove 14 are inclined planes. The two inclined planes form an angle therebetween.

In this embodiment, the epitaxial layer 16 comprises a GaN layer 24 and an AlGaN layer 26 disposed thereon.

In other embodiments, the epitaxial layer 16 may also comprise any monolayer or multilayers and suitable Group III-nitride layers.

In this embodiment, the semiconductor structure 10 further comprises a buffer layer (not shown) disposed between the silicon substrate 12 and the epitaxial layer 16.

In this embodiment, as shown in FIG. 2A, the gate 18 comprises a first portion 18′, a second portion 18″ and a third portion 18′″. The first portion 18′ is recessed downward to form a concave structure. For example, a part of the structure of the first portion 18′ is more adjacent to the epitaxial layer 16 than the other parts thereof. The second portion 18″ is connected to one end of the first portion 18′ and the epitaxial layer 16. The third portion 18′″ is connected to the other end of the first portion 18′ and the epitaxial layer 16.

In this embodiment, the semiconductor structure 10 further comprises a source/drain (28/30) respectively disposed above the silicon substrate 12 and the bottom 32 of the groove 14. The gate 18 and the source/drain (28/30) extend in a second direction 34, such as the z direction. The second direction 34 is parallel to the first direction 20.

In this embodiment, the source/drain (28/30) comprises a composite material of titanium, aluminum, nickel and silver.

In other embodiments, the source/drain (28/30) may also comprise any suitable metal or alloy material thereof.

In other embodiments, the source/drain (28/30) may further be disposed above the sidewalls 22 of the groove 14, as shown in FIG. 2A.

In other embodiments, a channel (not shown) is formed along the sidewalls 22 of the groove 14. The extension direction of the channel is perpendicular to the first direction 20.

In this embodiment, the epitaxial layer 16, the gate 18 and the source/drain (28/30) constitute a high electron mobility transistor (HEMT).

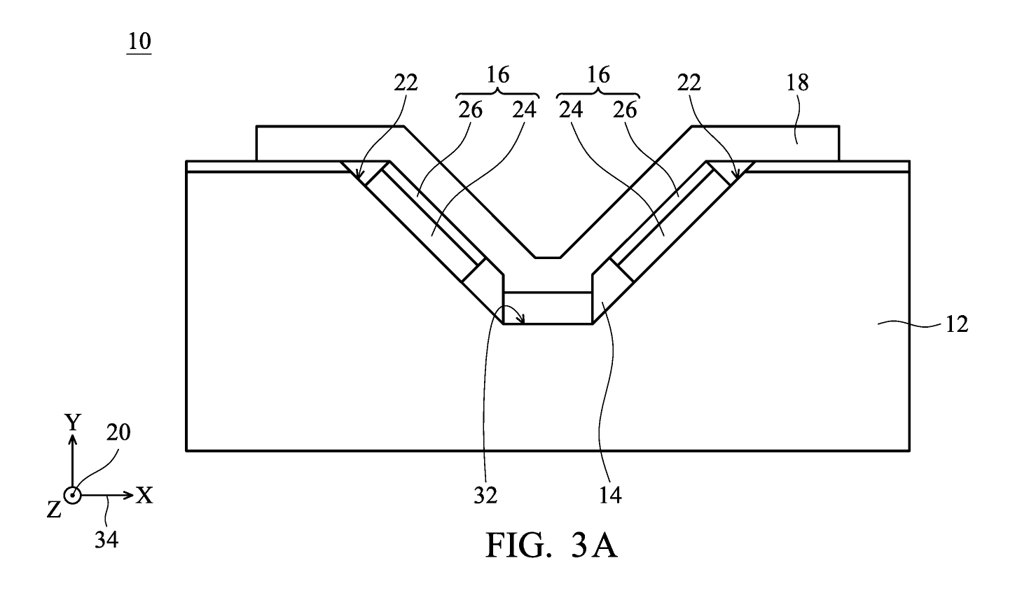

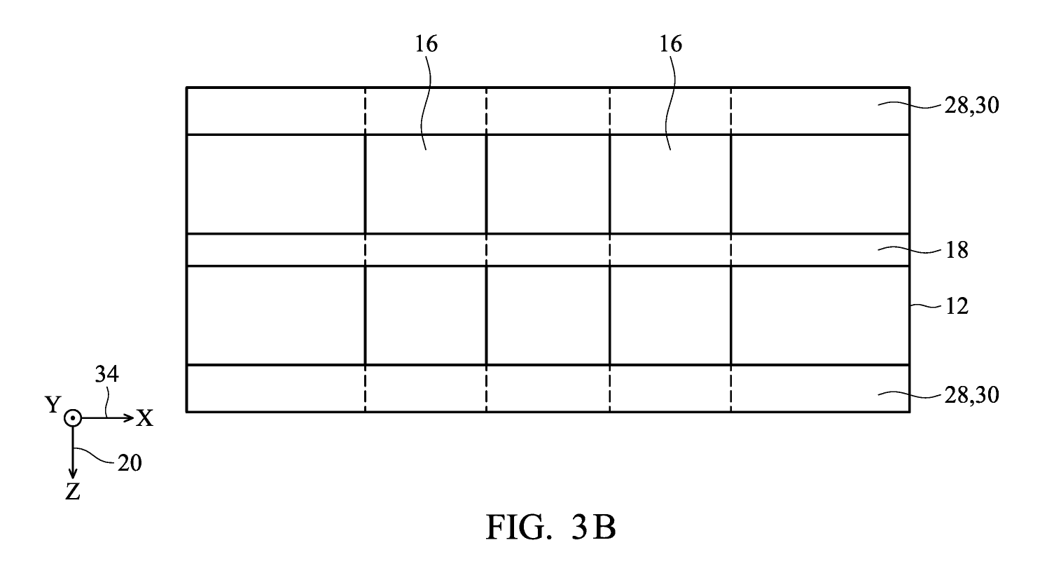

Referring to FIGS. 3A and 3B, in accordance with one embodiment of the disclosure, a semiconductor structure 10 is disclosed. FIG. 3A is a cross-sectional view of the semiconductor structure 10. FIG. 3B is a top view of the semiconductor structure 10 shown in FIG. 3A.

In this embodiment, the semiconductor structure 10 comprises a silicon substrate 12, a groove 14 having a bottom 32 and sidewalls 22, an epitaxial layer 16, and a gate 18. The groove 14 is disposed in the silicon substrate 12 and is extended in a first direction 20, such as the z direction. The epitaxial layer 16 is disposed on the sidewalls 22 of the groove 14. The gate 18 is disposed above the epitaxial layer 16, extended above the bottom 32 of the groove 14 and the silicon substrate 12, and electrically connected to the epitaxial layer 16. In one embodiment, the sidewalls 22 of the groove 14 have a lattice direction of (111). The epitaxial layer 16 comes into contact with a dielectric material layer 42 within the groove 14. The dielectric material layer 42 is located above the silicon substrate 12.

In this embodiment, the base of the silicon substrate 12 has a lattice direction of (100).

In this embodiment, the sidewalls 22 of the groove 14 are inclined planes. The two inclined planes form an angle therebetween.

In this embodiment, the epitaxial layer 16 comprises a GaN layer 24 and an AlGaN layer 26 disposed thereon.

In other embodiments, the epitaxial layer 16 may also comprise any monolayer or multilayers and suitable Group III-nitride layers.

In this embodiment, the semiconductor structure 10 further comprises a buffer layer (not shown) disposed between the silicon substrate 12 and the epitaxial layer 16.

In this embodiment, the semiconductor structure 10 further comprises a source/drain (28/30), as shown in FIG. 3B, respectively disposed above the epitaxial layer 16 and extended above the bottom 32 of the groove 14 and the silicon substrate 12. The gate 18 and the source/drain (28/30) extend in a second direction 34, such as the x direction. The second direction 34 is perpendicular to the first direction 20.

In this embodiment, the source/drain (28/30) comprises a composite material of titanium, aluminum, nickel and silver.

In other embodiments, the source/drain (28/30) may also comprise any suitable metal or alloy material thereof.

In other embodiments, a channel (not shown) is formed along the sidewalls 22 of the groove 14. The extension direction of the channel is parallel to the first direction 20.

In this embodiment, the epitaxial layer 16, the gate 18 and the source/drain (28/30) constitute a high electron mobility transistor (HEMT).

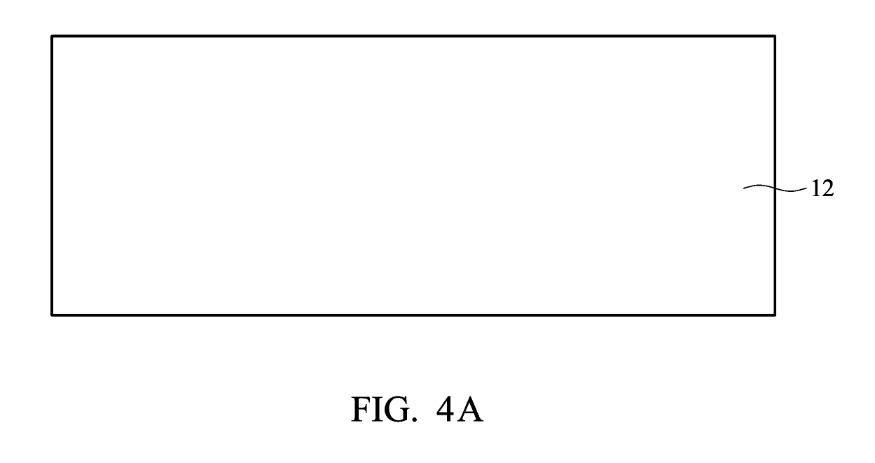

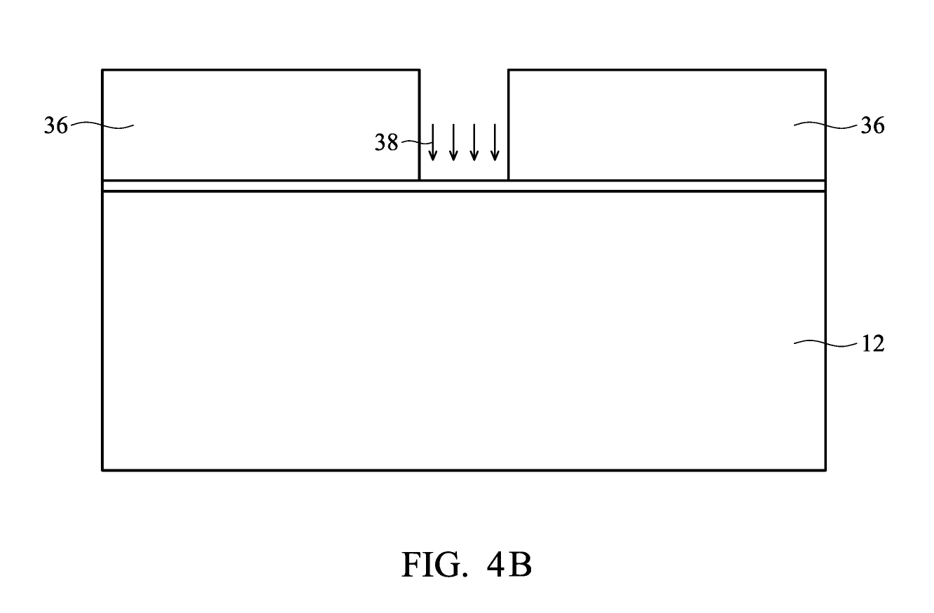

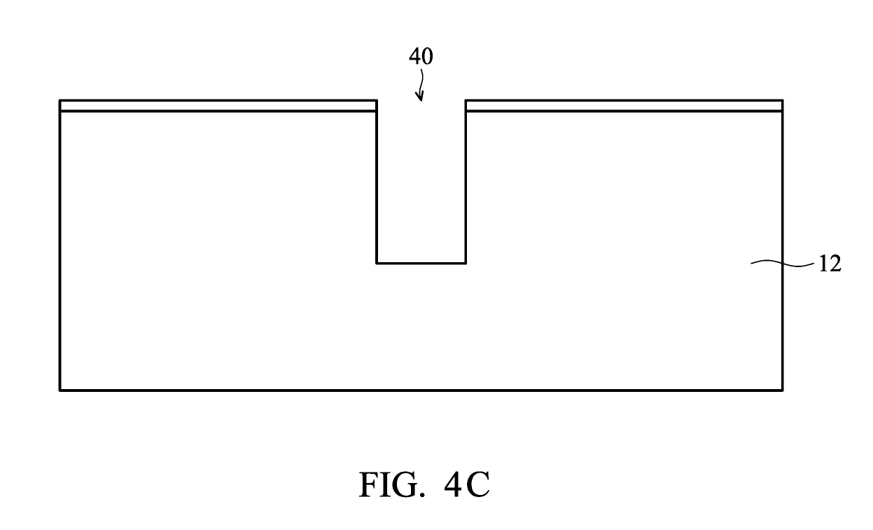

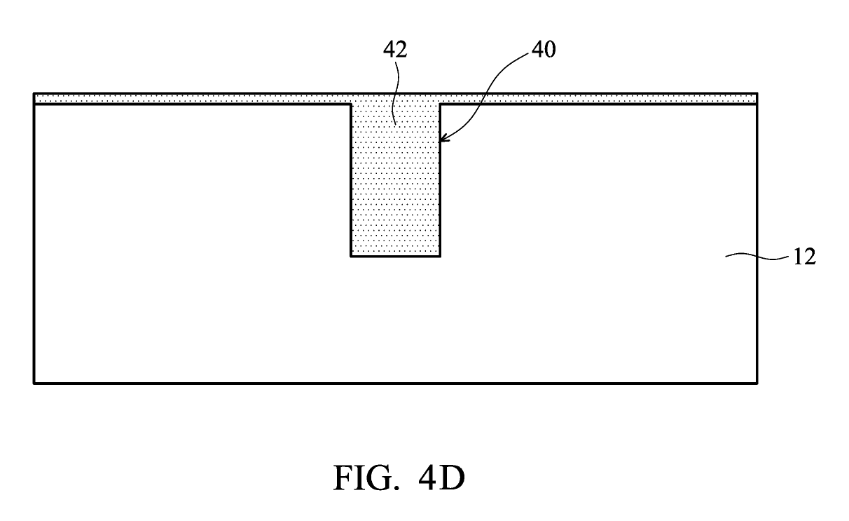

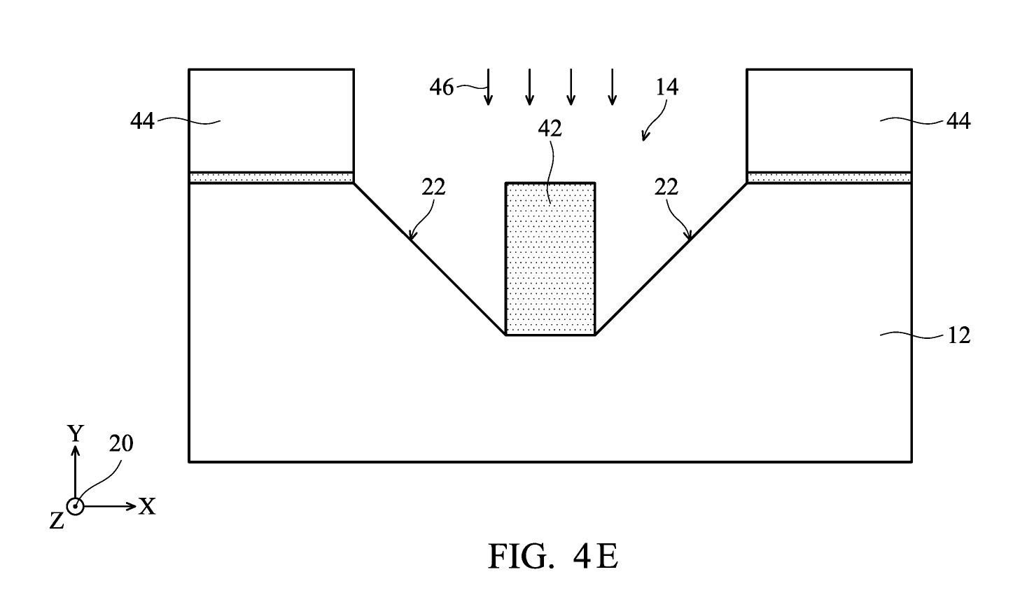

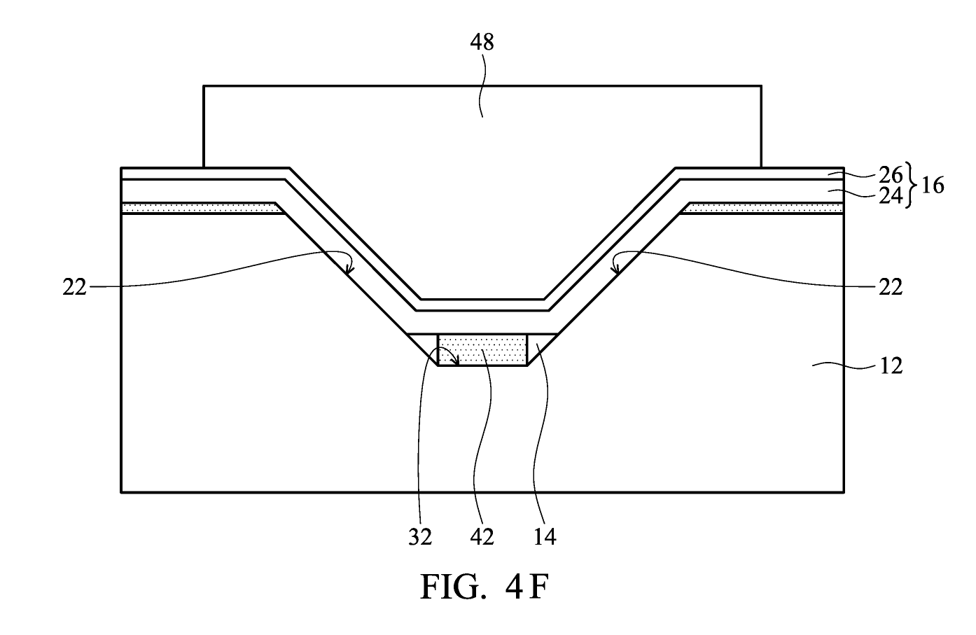

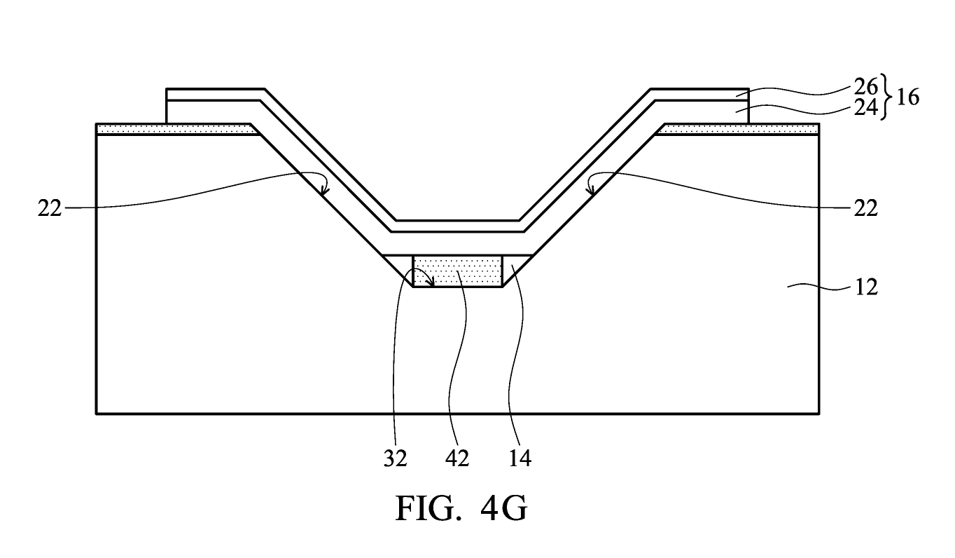

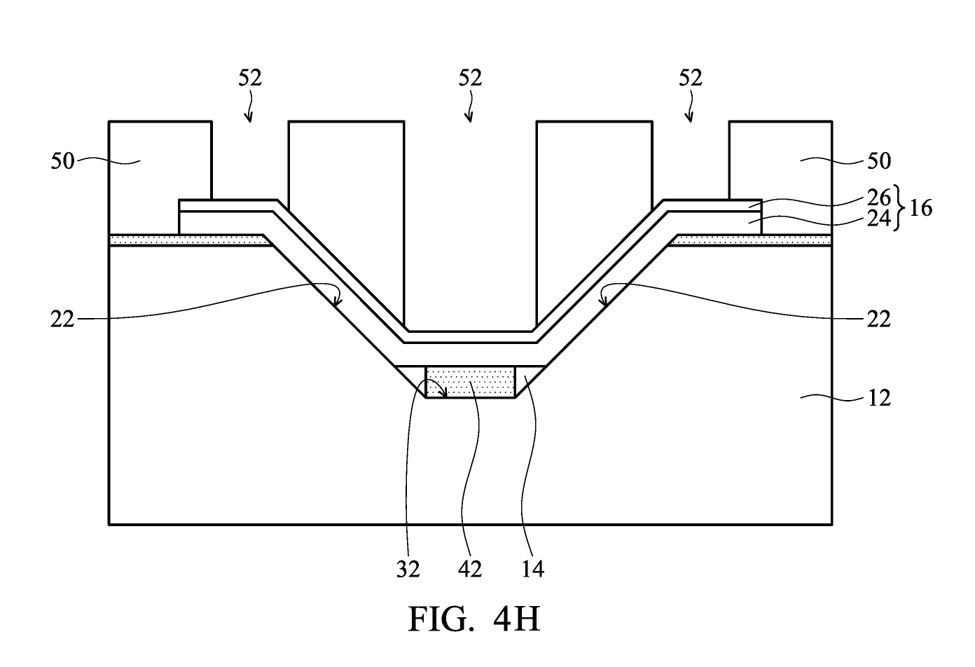

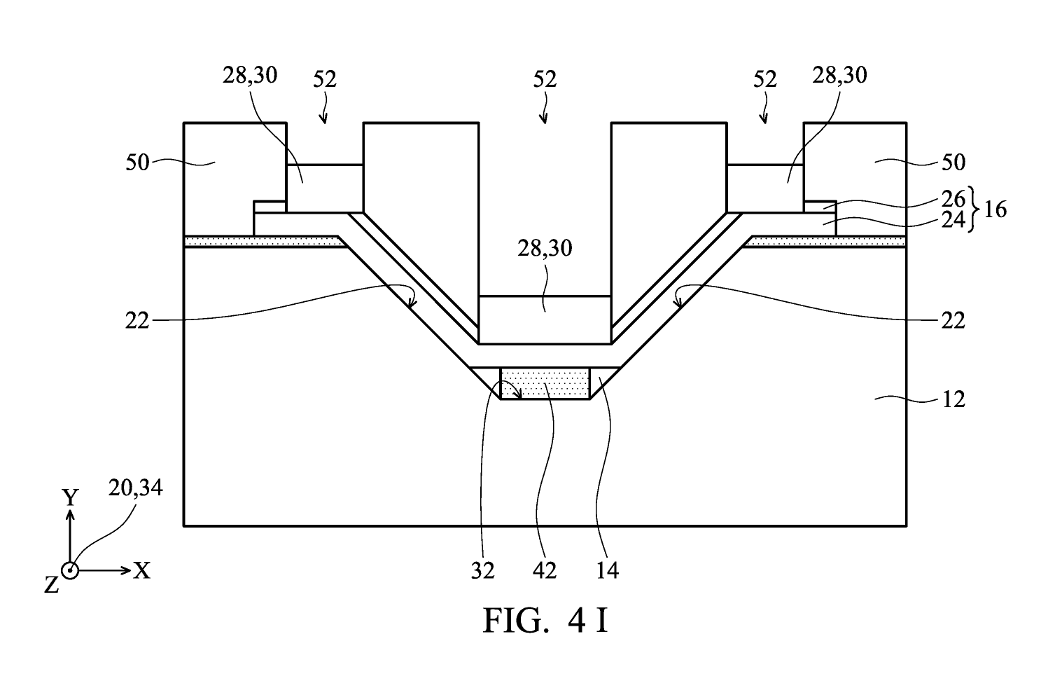

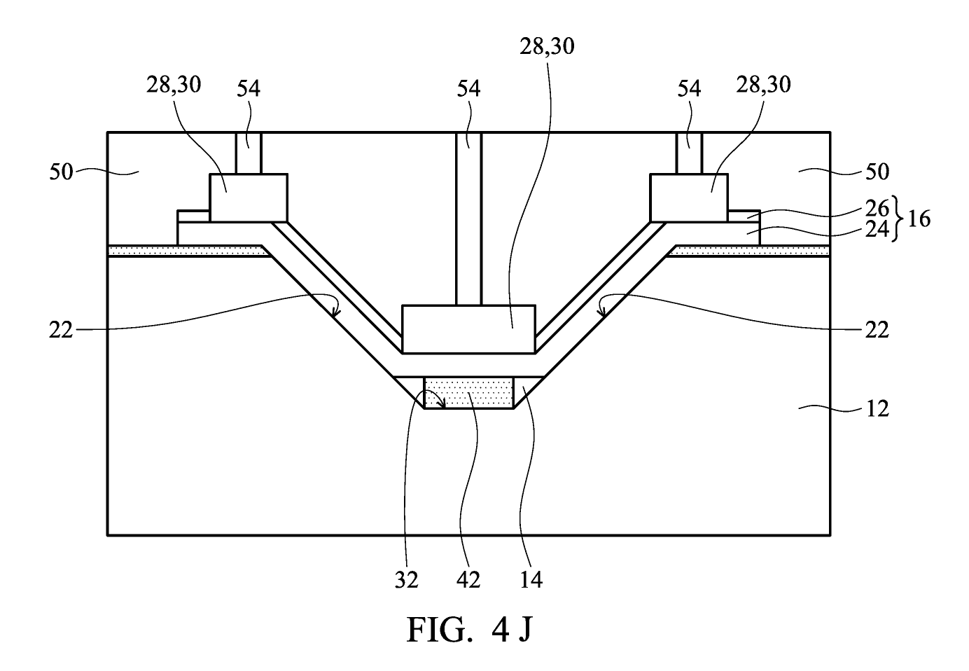

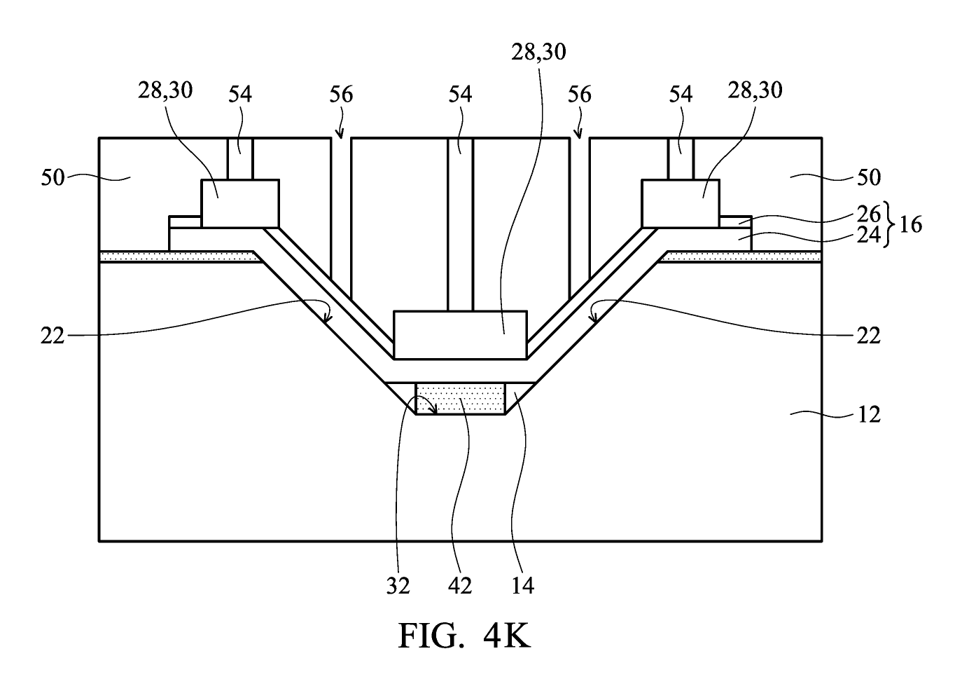

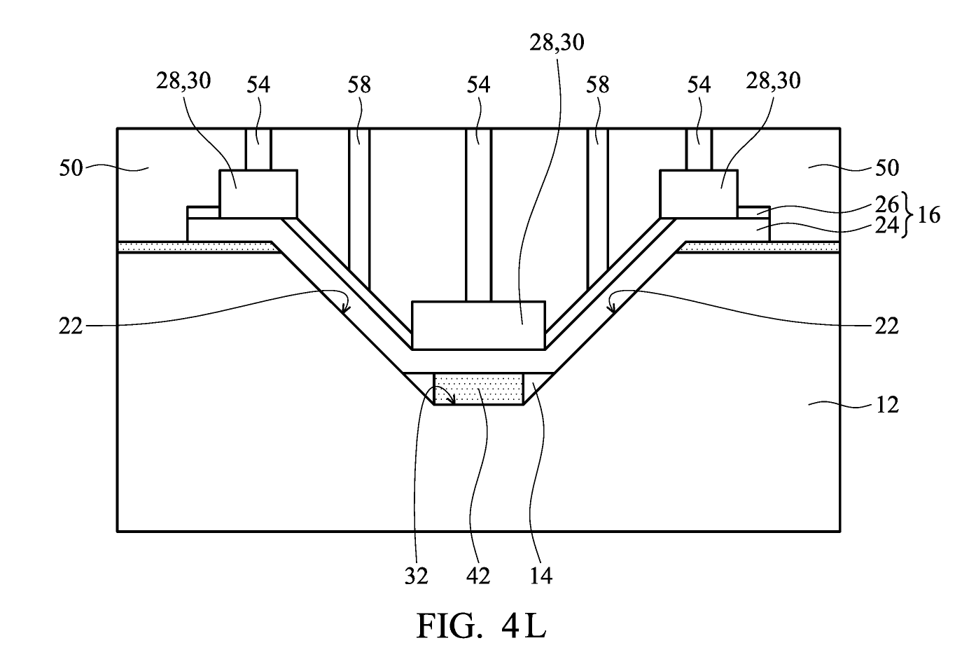

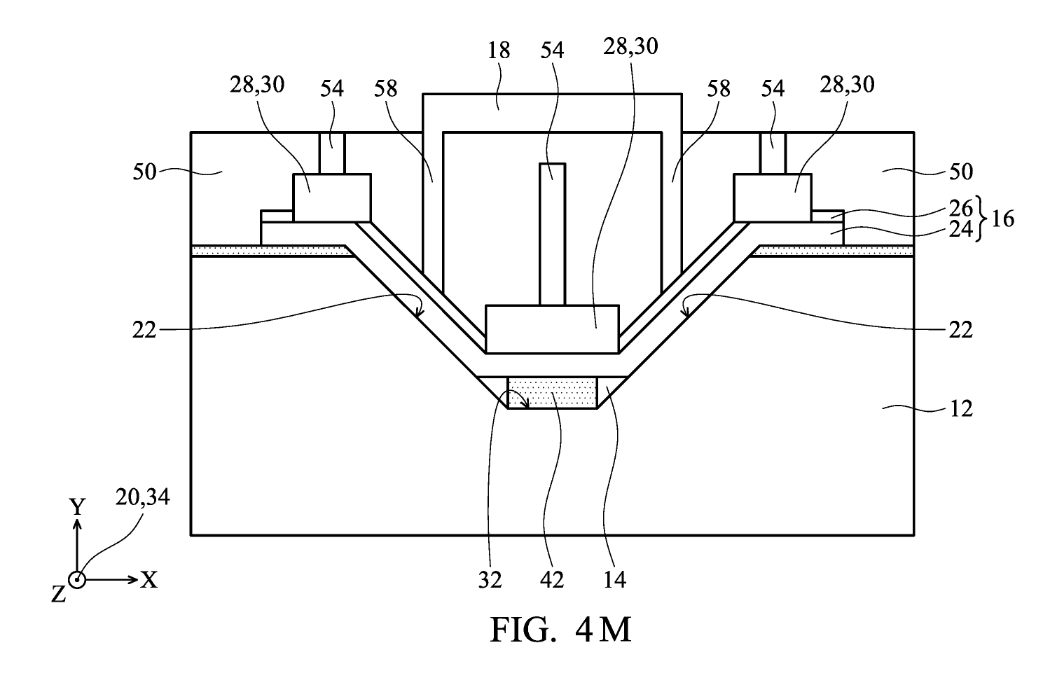

Referring to FIGS. 4A-4M, in accordance with one embodiment of the disclosure, a method for fabricating a semiconductor structure is disclosed. FIGS. 4A-4M is a cross-sectional view of the method for fabricating a semiconductor structure.

As shown in FIG. 4A, a silicon substrate 12 is provided and cleaned.

In this embodiment, the base of the silicon substrate 12 has a lattice direction of (100).

Next, as shown in FIG. 4B, a patterned photoresist layer 36 is formed on the silicon substrate 12. A development process is then performed using the patterned photoresist layer 36 as a mask. An etching process 38 is then performed on the silicon substrate 12, for example, an anisotropic dry etching process.

As shown in FIG. 4C, after the etching process, a trench 40 is formed in the silicon substrate 12. Next, the patterned photoresist layer 36 is removed.

Next, as shown in FIG. 4D, a dielectric material layer 42 is filled into the trench 40.

In this embodiment, the dielectric material layer 42 comprises silicon dioxide (SiO₂).

In other embodiments, the dielectric material layer 42 may also comprise other dielectric materials which are suitable for resisting the alkaline etching solution.

Next, as shown in FIG. 4E, a patterned photoresist layer 44 is formed on the silicon substrate 12. A development process is then performed using the patterned photoresist layer 44 as a mask. An etching process 46, for example an isotropic wet etching process, is then performed on the silicon substrate 12 to form a groove 14 with a bottom 32 and sidewalls 22 in the silicon substrate 12. The sidewalls 22 of the groove 14 have a lattice direction of (111). The groove 14 extends in a first direction 20, for example the z direction.

In this embodiment, the etching solution used to etch the silicon substrate 12 is potassium hydroxide (KOH).

In other embodiments, other suitable alkaline etching solutions used to etch the silicon substrate 12 may include sodium hydroxide (NaOH) and AZ400K developer.

In this embodiment, the sidewalls 22 of the groove 14 are inclined planes. The two inclined planes form an angle therebetween.

Next, as shown in FIG. 4F, the dielectric material layer 42 located in the groove 14 is thinned. An epitaxial layer 16 is then formed on the sidewalls 22 of the groove 14 extending above the bottom 32 of the groove 14 and the silicon substrate 12. Next, a patterned photoresist layer 48 is formed on a part of the epitaxial layer 16. The epitaxial layer 16 comes into contact with the dielectric material layer 42 within the groove 14. The dielectric material layer 42 is located above the silicon substrate 12.

In this embodiment, the dielectric material layer 42 located in the groove 14 is thinned with a hydrofluoric acid solution.

In other embodiments, another suitable acidic etching solution may be used to thin the dielectric material layer 42 located in the groove 14.

In this embodiment, the epitaxial layer 16 comprises a GaN layer 24 and an AlGaN layer 26 disposed thereon.

In other embodiments, the epitaxial layer 16 may also comprise any monolayer or multilayers and suitable Group III-nitride layers.

In other embodiments, a buffer layer (not shown in FIG. 4F) is formed between the silicon substrate 12 and the epitaxial layer 16 to alleviate the stress generated by the huge lattice dislocation formed between the silicon substrate 12 and the epitaxial layer 16.

In other embodiments, the buffer layer may comprise gallium nitride, gallium nitride/aluminum nitride of super lattice structure, aluminum nitride or another material.

Next, a part of the epitaxial layer 16 uncovered by the patterned photoresist layer 48 is etched using the patterned photoresist layer 48 as a mask to form the patterned epitaxial layer 16 to facilitate the subsequent isolation process performed between components, as shown in FIG. 4G.

In this embodiment, the part of the epitaxial layer 16 uncovered by the patterned photoresist layer 48 is etched using an inductively coupled plasma reactive ion etching process.

In other embodiments, another suitable dry etching process may be used to etch the part of the epitaxial layer 16 uncovered by the patterned photoresist layer 48.

Next, as shown in FIG. 4H, a patterned dielectric layer 50 is formed on the epitaxial layer 16 and the silicon substrate 12, exposing a plurality of source/drain predetermined regions 52.

Next, as shown in FIG. 4I, a composite material layer is deposited in the source/drain predetermined regions 52 to define the source/drain (28/30).

As shown in FIG. 4I, the source/drain (28/30) are respectively formed above the silicon substrate 12 and the bottom 32 of the groove 14.

In this embodiment, the source/drain (28/30) comprises a composite material of titanium, aluminum, nickel and silver.

In other embodiments, the source/drain (28/30) may also comprise any suitable metal or alloy material thereof.

In other embodiments, the source/drain (28/30) may extend further from above the silicon substrate 12 to above the sidewalls 22 of the groove 14, as shown in FIG. 4I.

Next, as shown in FIG. 4J, a plurality of plugs 54 is formed in the dielectric layer 50 to electrically connect to the source/drain (28/30).

Next, as shown in FIG. 4K, the dielectric layer 50 is etched to form a plurality of etching vias 56 therein.

Next, as shown in FIG. 4L, a gate metal 58 is filled into the etching vias 56 to electrically connect to the epitaxial layer 16 which is located on the sidewalls 22 of the groove 14.

Next, as shown in FIG. 4M, a gate 18 is formed on the dielectric layer 50 to electrically connect to the epitaxial layer 16.

In this embodiment, the gate 18 is a plane structure, as shown in FIG. 4M.

In other embodiments, the gate 18 may have other structural features, such as a concave structure. That is, a part of the structure of the gate 18 is more adjacent to the epitaxial layer 16 than the other parts thereof, as shown in FIG. 2A.

In this embodiment, the gate 18 and the source/drain (28/30) extend in a second direction 34, such as the z direction. The second direction 34 is parallel to the first direction 20.

In this embodiment, the epitaxial layer 16, the gate 18 and the source/drain (28/30) constitute a high electron mobility transistor (HEMT).

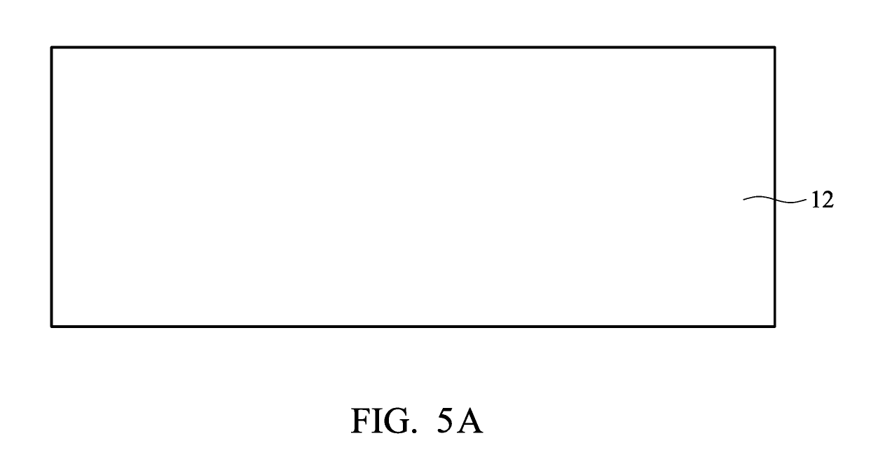

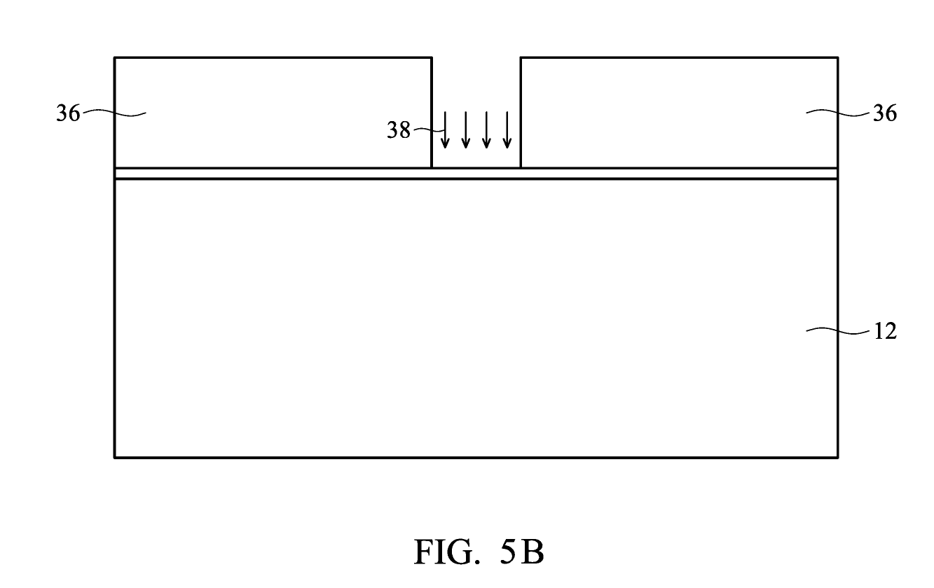

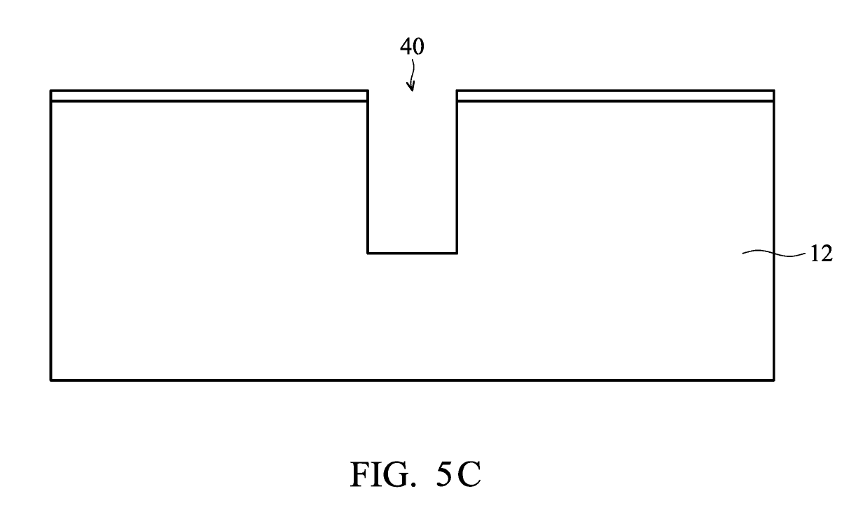

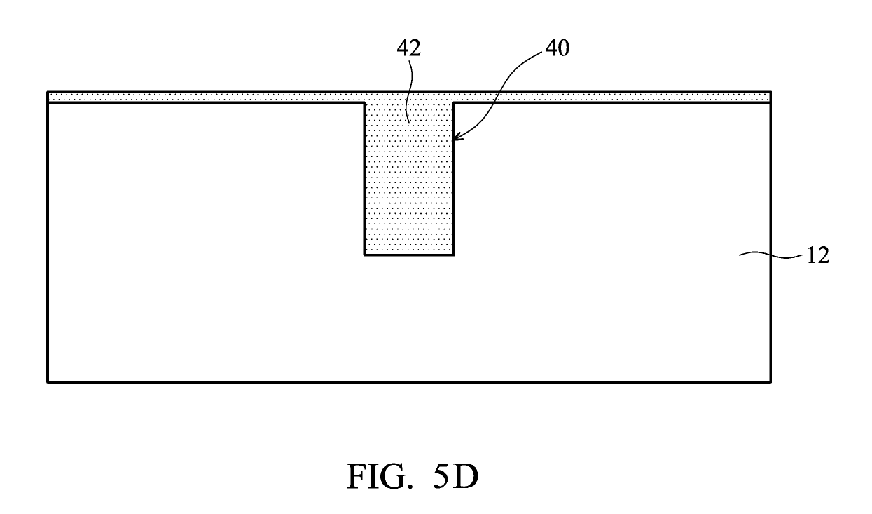

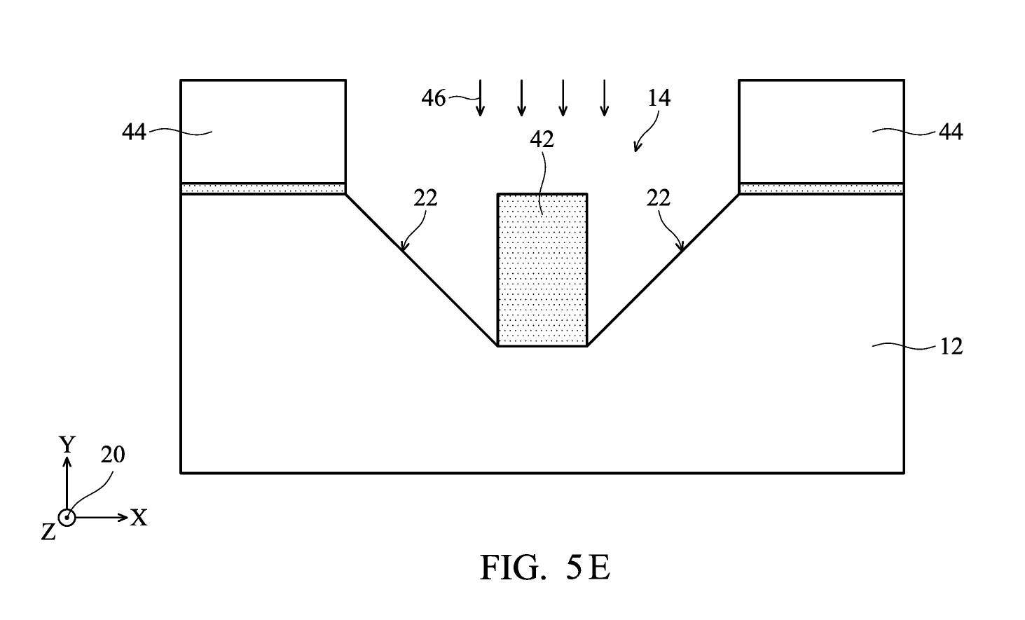

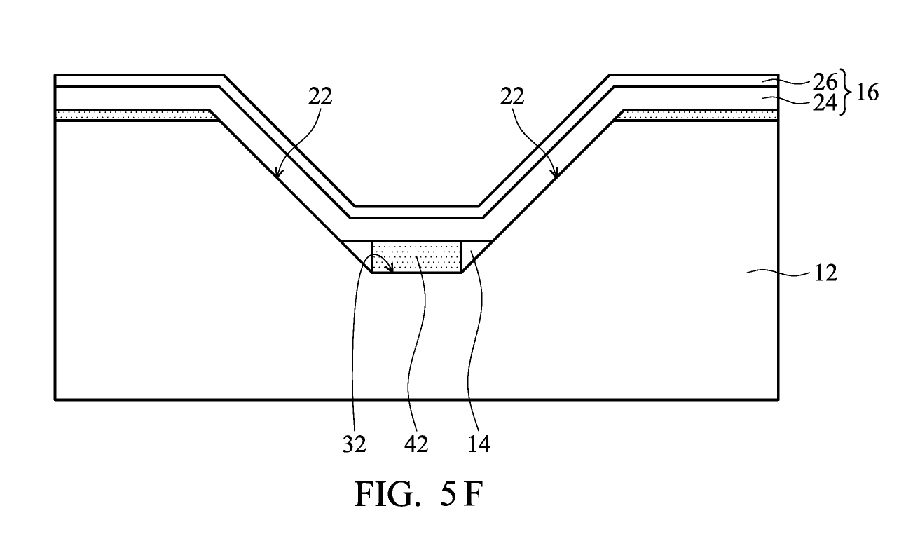

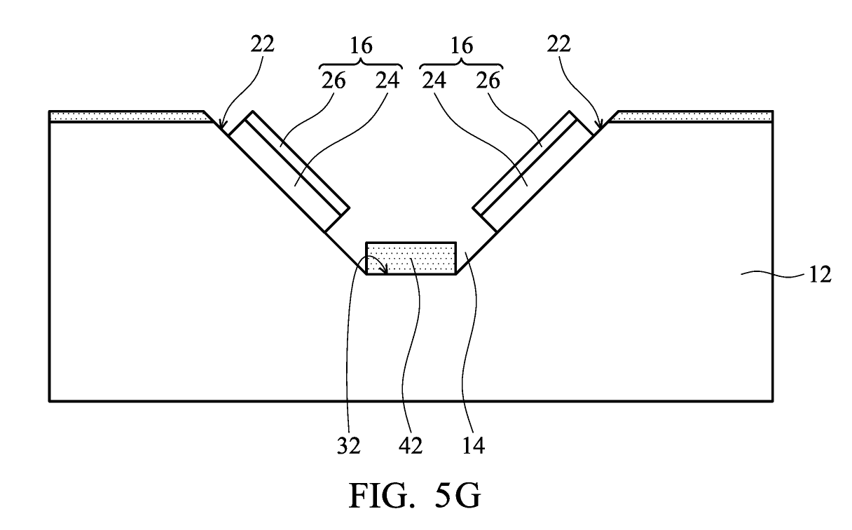

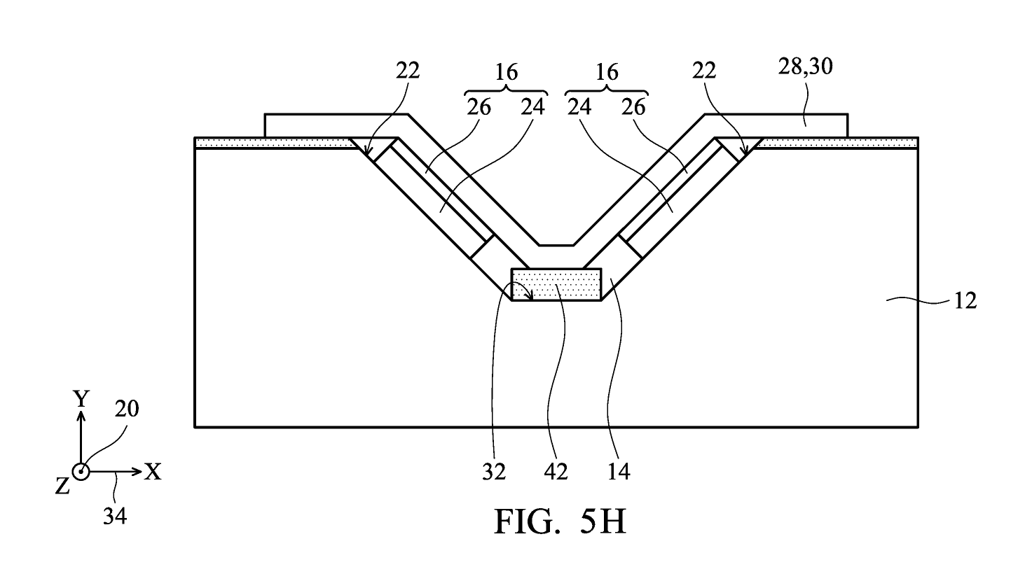

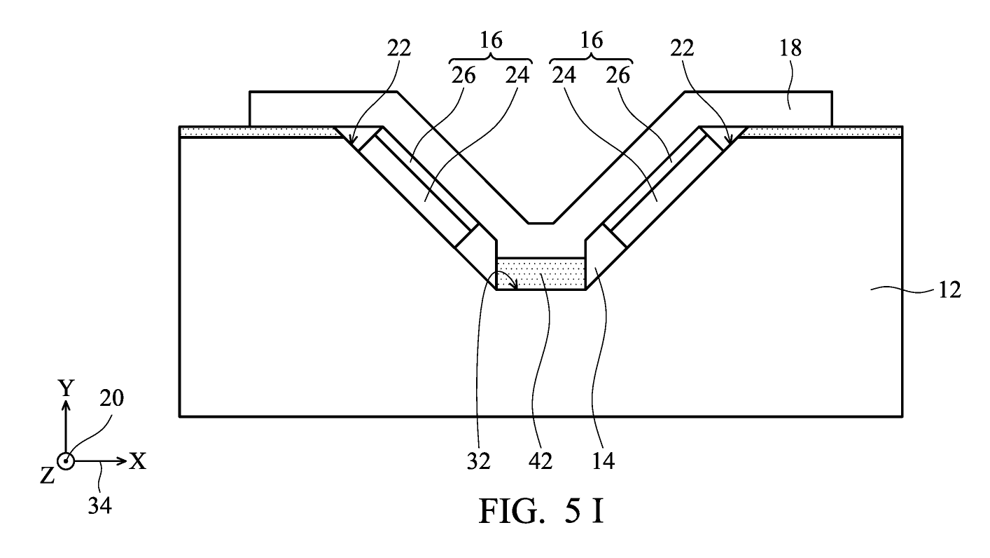

Referring to FIGS. 5A-5I, in accordance with one embodiment of the disclosure, a method for fabricating a semiconductor structure is disclosed. FIGS. 5A-5I is a cross-sectional view of the method for fabricating a semiconductor structure.

As shown in FIG. 5A, a silicon substrate 12 is provided and cleaned.

In this embodiment, the base of the silicon substrate 12 has a lattice direction of (100).

Next, as shown in FIG. 5B, a patterned photoresist layer 36 is formed on the silicon substrate 12. A development process is then performed using the patterned photoresist layer 36 as a mask. An etching process 38 is then performed on the silicon substrate 12, for example, an anisotropic dry etching process.

As shown in FIG. 5C, after the etching process, a trench 40 is formed in the silicon substrate 12. Next, the patterned photoresist layer 36 is removed.

Next, as shown in FIG. 5D, a dielectric material layer 42 is filled into the trench 40.

In this embodiment, the dielectric material layer 42 comprises silicon dioxide (SiO₂).

In other embodiments, the dielectric material layer 42 may also comprise other dielectric materials which are suitable for resisting the alkaline etching solution.

Next, as shown in FIG. 5E, a patterned photoresist layer 44 is formed on the silicon substrate 12. A development process is then performed using the patterned photoresist layer 44 as a mask. An etching process 46, for example an isotropic wet etching process, is then performed on the silicon substrate 12 to form a groove 14 with a bottom 32 and sidewalls 22 in the silicon substrate 12. The sidewalls 22 of the groove 14 have a lattice direction of (111). The groove 14 extends in a first direction 20, for example the z direction.

In this embodiment, the etching solution used to etch the silicon substrate 12 is potassium hydroxide (KOH).

In other embodiments, other suitable alkaline etching solutions used to etch the silicon substrate 12 may include sodium hydroxide (NaOH) and AZ400K developer.

In this embodiment, the sidewalls 22 of the groove 14 are inclined planes. The two inclined planes form an angle therebetween.

Next, as shown in FIG. 5F, the dielectric material layer 42 located in the groove 14 is thinned. An epitaxial layer 16 is then formed on the sidewalls 22 of the groove 14 extending above the bottom 32 of the groove 14 and the silicon substrate 12. Next, a patterned photoresist layer (not shown) is formed on a part of the epitaxial layer 16. The epitaxial layer 16 comes into contact with the dielectric material layer 42 within the groove 14. The dielectric material layer 42 is located above the silicon substrate 12.

In this embodiment, the dielectric material layer 42 located in the groove 14 is thinned with a hydrofluoric acid solution.

In other embodiments, another suitable acidic etching solution may be used to thin the dielectric material layer 42 located in the groove 14.

In this embodiment, the epitaxial layer 16 comprises a GaN layer 24 and an AlGaN layer 26 disposed thereon.

In other embodiments, the epitaxial layer 16 may also comprise any monolayer or multilayers and suitable Group III-nitride layers.

In other embodiments, a buffer layer (not shown in FIG. 5F) is formed between the silicon substrate 12 and the epitaxial layer 16 to alleviate the stress generated by the huge lattice dislocation formed between the silicon substrate 12 and the epitaxial layer 16.

In other embodiments, the buffer layer may comprise gallium nitride, gallium nitride/aluminum nitride of super lattice structure, aluminum nitride or other materials.

Next, a part of the epitaxial layer 16 uncovered by the patterned photoresist layer is etched using the patterned photoresist layer as a mask to form the patterned epitaxial layer 16.

In this embodiment, the patterned epitaxial layer 16 is merely located on the sidewalls 22 of the groove 14, as shown in FIG. 5G.

In this embodiment, the part of the epitaxial layer 16 uncovered by the patterned photoresist layer is etched in an inductively coupled plasma reactive ion etching process.

In other embodiments, another suitable dry etching process may be used to etch the part of the epitaxial layer 16 uncovered by the patterned photoresist layer.

Next, as shown in FIG. 5H, a dielectric layer (not shown) is formed above the groove 14 and the silicon substrate 12. The dielectric layer is then etched to form a plurality of gate/source/drain predetermined regions (not shown). Next, a composite material layer is deposited in the source/drain predetermined regions to define a source/drain (28/30).

In this embodiment, the source/drain (28/30), as shown in FIG. 3B, is respectively disposed above the epitaxial layer 16 and extend above the bottom 32 of the groove 14 and the silicon substrate 12.

In this embodiment, the source/drain (28/30) comprises a composite material of titanium, aluminum, nickel and silver.

In other embodiments, the source/drain (28/30) may also comprise any suitable metal or alloy material thereof.

In other embodiments, the source/drain (28/30) may extend further from above the silicon substrate 12 to above the sidewalls 22 of the groove 14, as shown in FIG. 4I.

Next, as shown in FIG. 5I, a gate 18 is formed above the epitaxial layer 16, extending above the bottom 32 of the groove 14 and the silicon substrate 12, and electrically connected to the epitaxial layer 16.

In this embodiment, the gate 18 and the source/drain (28/30) extend in a second direction 34, such as the x direction. The second direction 34 is perpendicular to the first direction 20.

In this embodiment, the epitaxial layer 16, the gate 18 and the source/drain (28/30) constitute a high electron mobility transistor (HEMT).

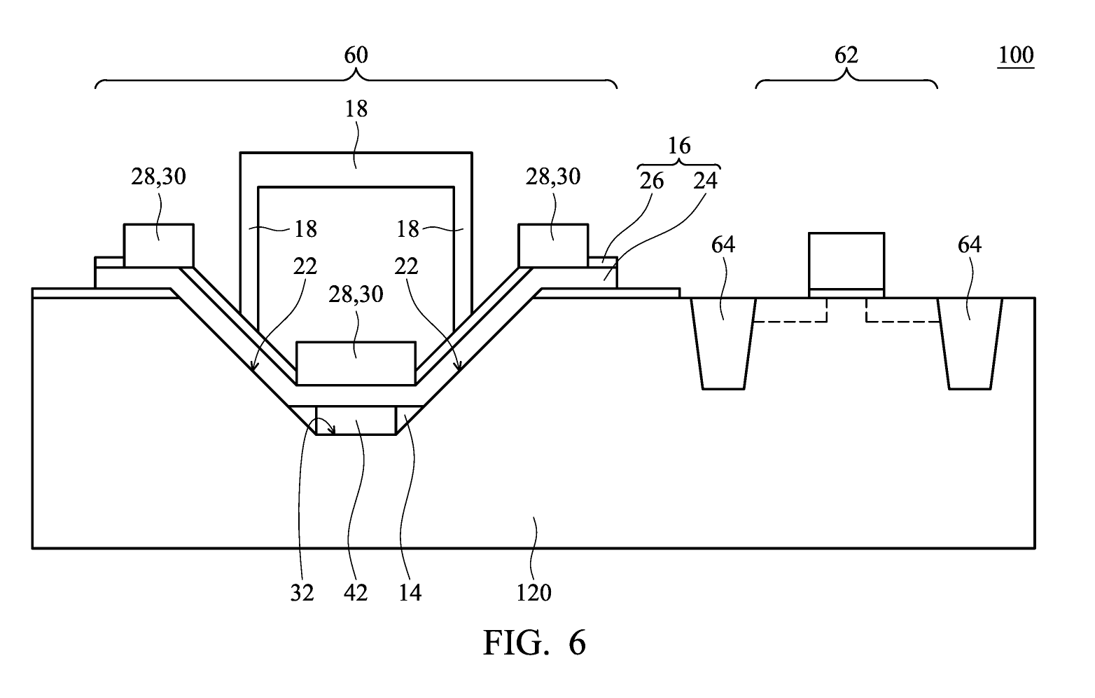

Referring to FIG. 6, in accordance with one embodiment of the disclosure, a semiconductor structure 100 is disclosed. FIG. 6 is a cross-sectional view of the semiconductor structure 100.

In the semiconductor structure 100 (a silicon substrate 120), the component at one side thereof is a high electron mobility transistor (HEMT) 60 comprising the epitaxial layer 16, the gate 18 and the source/drain (28/30) as shown in FIG. 1A. The component at the other side of the semiconductor structure 100 (the silicon substrate 120) is a complementary metal oxide semiconductor (CMOS) circuit 62. The high electron mobility transistor (HEMT) 60 is isolated from the complementary metal oxide semiconductor (CMOS) circuit 62 by a shallow trench isolation (STI) 64.

In this embodiment, the base of the silicon substrate 120 has a lattice direction of (100).

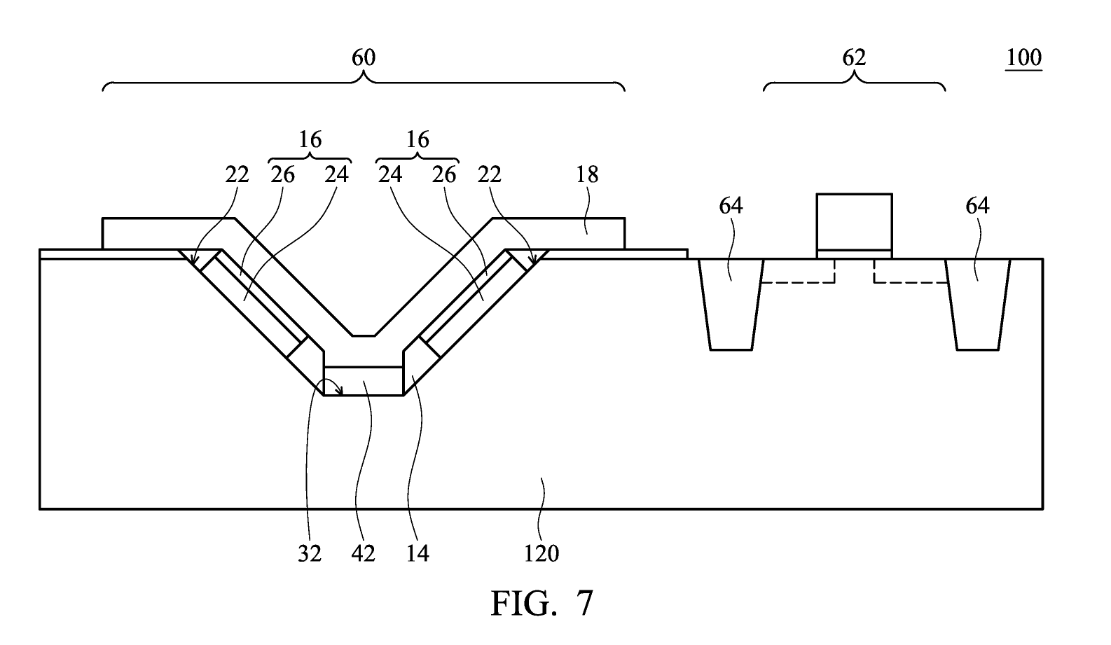

Referring to FIG. 7, in accordance with one embodiment of the disclosure, a semiconductor structure 100 is disclosed. FIG. 7 is a cross-sectional view of the semiconductor structure 100.

In the semiconductor structure 100 (a silicon substrate 120), the component at one side thereof is a high electron mobility transistor (HEMT) 60 comprising the epitaxial layer 16, the gate 18 and the source/drain (28/30) as shown in FIG. 3A. The component at the other side of the semiconductor structure 100 (the silicon substrate 120) is a complementary metal oxide semiconductor (CMOS) circuit 62. The high electron mobility transistor (HEMT) 60 is isolated from the complementary metal oxide semiconductor (CMOS) circuit 62 by a shallow trench isolation (STI) 64.

In this embodiment, the base of the silicon substrate 120 has a lattice direction of (100).

The present disclosure utilizes an alkaline etching solution (e.g., potassium hydroxide) to perform a simple wet etching on a conventional silicon (100) substrate to form a silicon (111) bevel in the silicon (100) substrate for deposition of a high electron mobility transistor (HEMT)(Group III-nitride layer) thereon. Therefore, a high electron mobility transistor (HEMT) with high electron mobility, high breakdown voltage and heat resistance properties and a complementary metal oxide semiconductor (CMOS) circuit are capable of being integrated on the same silicon (100) substrate at the same time to enhance the ability of the system on chip to handle power and RF power signals.

It will be apparent to those skilled in the art that various modifications and variations can be made to the disclosed embodiments. It is intended that the specification and examples be considered as exemplary only, with the true scope of the disclosure being indicated by the following claims and their equivalents.

What is claimed is:

1. A semiconductor structure, comprising:
a silicon substrate having a groove with a bottom and sidewalls, wherein the sidewalls of the groove have a lattice direction of (111), and the groove extends in a first direction;
an epitaxial layer disposed on the sidewalls of the groove; and
a gate disposed above the epitaxial layer and electrically connected to the epitaxial layer.

2. The semiconductor structure as claimed in claim 1, wherein the silicon substrate has a lattice direction of (100).

3. The semiconductor structure as claimed in claim 1, wherein the sidewalls of the groove are inclined planes.

4. The semiconductor structure as claimed in claim 1, wherein the epitaxial layer is formed on the sidewalls of the groove, and extends above the bottom of the groove and the silicon substrate.

5. The semiconductor structure as claimed in claim 1, wherein the epitaxial layer comprises Group III nitrides.

6. The semiconductor structure as claimed in claim 4, further comprising a source and a drain respectively disposed above the silicon substrate and the bottom of the groove, wherein the gate, the source and the drain extend in a second direction that is parallel to the first direction.

7. The semiconductor structure as claimed in claim 6, wherein the source and the drain are further disposed above the sidewalls of the groove.

8. The semiconductor structure as claimed in claim 6, wherein the epitaxial layer, the gate, the source and the drain constitute a high electron mobility transistor (HEMT).

9. The semiconductor structure as claimed in claim 8, further comprising a complementary metal oxide semiconductor (CMOS) circuit disposed in the silicon substrate, wherein the complementary metal oxide semiconductor (CMOS) circuit is isolated from the high electron mobility transistor (HEMT).

10. The semiconductor structure as claimed in claim 1, further comprising a source and a drain respectively disposed above the epitaxial layer, wherein the gate, the source and the drain extend above the bottom of the groove and the silicon substrate, and the gate, the source and the drain extend in a second direction that is perpendicular to the first direction.

11. The semiconductor structure as claimed in claim 10, wherein the epitaxial layer, the gate, the source and the drain constitute a high electron mobility transistor (HEMT).

12. The semiconductor structure as claimed in claim 11, further comprising a complementary metal oxide semiconductor (CMOS) circuit disposed in the silicon substrate, wherein the complementary metal oxide semiconductor (CMOS) circuit is isolated from the high electron mobility transistor (HEMT).

13. A method for fabricating a semiconductor structure, comprising:
providing a silicon substrate;
etching the silicon substrate to form a groove with a bottom and sidewalls in the silicon substrate, wherein the sidewalls of the groove have a lattice direction of (111), and the groove extends in a first direction;
forming an epitaxial layer on the sidewalls of the groove; and
forming a gate above the epitaxial layer to electrically connect to the epitaxial layer.

14. The method for fabricating a semiconductor structure as claimed in claim 13, wherein the silicon substrate has a lattice direction of (100).

15. The method for fabricating a semiconductor structure as claimed in claim 13, wherein the silicon substrate is etched using potassium hydroxide or sodium hydroxide to form the groove in the silicon substrate.

16. The method for fabricating a semiconductor structure as claimed in claim 13, wherein the sidewalls of the groove are inclined planes.

17. The method for fabricating a semiconductor structure as claimed in claim 13, wherein the epitaxial layer is formed on the sidewalls of the groove, and extends above the bottom of the groove and the silicon substrate.

18. The method for fabricating a semiconductor structure as claimed in claim 13, wherein the epitaxial layer comprises Group III nitrides.

19. The method for fabricating a semiconductor structure as claimed in claim 17, further comprising forming a source and a drain respectively above the silicon substrate and the bottom of the groove, wherein the gate, the source and the drain extend in a second direction that is parallel to the first direction.

20. The method for fabricating a semiconductor structure as claimed in claim 19, wherein the source and the drain are further extended from above the silicon substrate to above the sidewalls of the groove.

21. The method for fabricating a semiconductor structure as claimed in claim 19, wherein the epitaxial layer, the gate, the source and the drain constitute a high electron mobility transistor (HEMT).

22. The method for fabricating a semiconductor structure as claimed in claim 21, further comprising forming a complementary metal oxide semiconductor (CMOS) circuit in the silicon substrate, wherein the complementary metal oxide semiconductor (CMOS) circuit is isolated from the high electron mobility transistor (HEMT).

23. The method for fabricating a semiconductor structure as claimed in claim 13, further comprising forming a source and a drain respectively above the epitaxial layer, wherein the gate, the source and the drain extend above the bottom of the groove and the silicon substrate, and the gate, the source and the drain extend in a second direction that is perpendicular to the first direction.

24. The method for fabricating a semiconductor structure as claimed in claim 23, wherein the epitaxial layer, the gate, the source and the drain constitute a high electron mobility transistor (HEMT).

25. The method for fabricating a semiconductor structure as claimed in claim 24, further comprising forming a complementary metal oxide semiconductor (CMOS) circuit in the silicon substrate, wherein the complementary metal oxide semiconductor (CMOS) circuit is isolated from the high electron mobility transistor (HEMT).
